(19) United States
(12) Patent Application Publication
(10) Pub. No.: US 2011/0005814 A1
(43) Pub. Date: Jan. 13, 2011

(54) CIRCUIT BOARD VIA STRUCTURE AND METHOD FORMING THE SAME

(75) Inventors: Peng Liu, Shanghai (CN); Yu Zhang, Shanghai (CN); Shih-Kuang Tsai, Shanghai (CN)

Correspondence Address: MCDERMOTT WILL & EMERY LLP, 600 13TH STREET, N.W., WASHINGTON, DC, 20005-3096, US

(73) Assignees: INVENTEC APPLIANCES (Shanghai) CO., LTD.; INVENTEC APPLIANCES CORP.

(21) Appl. No.: 12/794,081

(22) Filed: Jun. 4, 2010

(30) Foreign Application Priority Data
Jul. 10, 2009 (CN) 200910054625.5

(51) Int. Cl. H05K 1/09; H05K 1/11; C25D 5/02; H05K 3/42; H05K 3/32

(52) U.S. Cl. 174/257; 174/266; 205/125; 29/852; 29/831

(57) ABSTRACT

A printed circuit board (“PCB”) (100) includes a first routing layer (110), a second routing layer (120) and a via hole structure (150) electrically connecting the two routing layers. The via hole structure (150) includes a connecting hole (158) extending between the first routing layer (110) and the second routing layer (120), an inner conductor (154) positioned in the connecting hole (158), an outer conductor (152) substantially surrounds the inner conductor (154), and an insulating medium (156) positioned between the inner conductor and the outer conductor. The outer conductor (152) is insulated from the inner conductor (154), the outer conductor (152) is configured to connected to the ground, and the inner conductor (154) is configured to transmit signals.

### FIELD OF INVENTION

The present invention relates to via hole structures between different routing layers and printed circuit boards (“PCBs”) having such via hole structures.

### BACKGROUND OF INVENTION

With the development of very large scale integrated (VLSI) circuit technologies, printed circuit boards (“PCBs”) have been widely used. Generally, there are three types of PCBs: single layer PCB, double layer PCB and multi-layer PCB.

Generally, a single layer PCB is a circuit board that only has one side clad with copper, and has electronic components placed on the other side. The copper-clad side is for routing and components welding. A double layer PCB is a circuit board that has both sides clad with copper, and the two copper layers are often referred to as the top layer and the bottom layer. Wires can be routed on both copper-clad sides. The top layer is generally for placing components thereon, and the bottom layer is generally for welding the components. The multi layer PCB is a circuit board including multiple conductive layers. In addition to the top layer and the bottom layer, the multi layer PCB also includes one or more inner layers. The top layer and the bottom layer are substantially same as those of the double layer PCB, and the inner layers are insulated from each other and may be conductor layers, signal layers, power layers and/or ground layers.

With the increasing complexity of the wire layout of the PCBs, and due to the limitation of the routing area of the PCBs, the double layer PCBs and the multi layer PCBs are now widely used. A double layer PCB or a multi-layer PCB includes at least one via hole for realizing the connection between different layers. The via hole is one of the main components of the multi-layer PCB, and often counts for as much as 30% to 40% of the manufacturing cost of the PCB. Simply speaking, every hole on the PCB may be called as a via hole. In terms of functions, the via holes can be classified into two types, one for the electrical connection between layers; and another for the fixation and/or orientation of devices. In terms of manufacturing processes, the via holes can be classified into three types: blind via holes, buried via holes, and through via holes. The blind via holes are positioned on the top layer or the bottom layer of the PCB, and have a certain depth for connecting the wire on the top/bottom layer and the wire on an inner layer. The buried via hole is a connecting hole positioned on the inner layer of the PCB, and does not extend to the outer surface of the PCB. Both the blind via hole and the buried via hole are positioned and formed on the inner layer of the PCB through a via hole forming process before layer lamination. A plurality of inner layers may be formed during the via hole forming process. The through via holes generally run through the whole PCB. The through via hole is for realizing internal interconnections, or is used as a component installation fixation hole. Since the trough via hole is easy to realize and costs relatively low, most of the PCBs utilize the through via hole instead of the other two types of the via holes.

FIG. 1 illustrates a conventional via hole structure of a multi-layer PCB 5. The PCB 5 includes a top layer 10, a bottom layer 20, a radio frequency wire 30 arranged on the top layer 10, at least one electronic component 40 placed on the bottom layer 20, and a via hole structure 50 extending through the PCB 5. The via hole structure 50 connects the radio frequency wire 30 with the electronic component 40 positioned on two sides of the PCB 5, thereby facilitating the transmission of radio frequency signal between the radio frequency wire 30 and the electronic component 40. However, the conductor of the via hole structure 50 is exposed to the air, which is subject to the influence of various electromagnetic radiation from outside. Specifically, when the PCB 5 includes a radio frequency signal wire and the wire is positioned close to the via hole, since the frequency of radio frequency signal is very high, signal leakage may occur and affect signal quality due to impedance mismatch, which causes an adverse impact to the system using the PCB 5.

### BRIEF DESCRIPTION OF THE DRAWINGS

FIG. 1 is a conventional via hole structure of a double layer PCB.

FIG. 2 is a perspective view of a double layer PCB according to an embodiment of the present invention.

FIG. 3 is a cross-sectional view of a central portion of a via hole structure illustrated in FIG. 2.

FIG. 4 is a perspective view of the via hole structure illustrated in FIG. 2.

FIG. 5 is a cross-sectional view of a central portion of a via hole structure according to another embodiment of the present invention.

### DETAILED DESCRIPTION

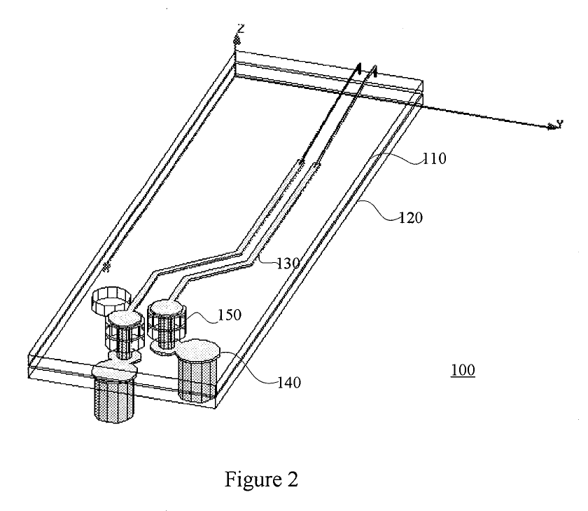

FIG. 2 is a perspective view of a double layer printed circuit board (“PCB”) 100 according to an embodiment of the present invention. The PCB 100 includes a top routing layer 110 and a bottom routing layer 120. The top routing layer 110 includes a circuit (not shown) having a radio frequency wire 130 arranged thereon, and the bottom routing layer 120 includes at least one electronic component 140 positioned thereon. The PCB 100 also includes a via hole structure 150 formed therein. The via hole structure 150 connects the radio frequency wire 130 with the electronic component 140, thereby facilitating the transmission of radio frequency signals between the wire 130 and the component 140. It is appreciated that the electronic component 140 may be an electrical device connected with the via hole structure 150 or a welding foot (not shown). It is also appreciated that the top routing layer 110 and the bottom routing layer 120 may include a radio frequency circuit as well as any other type of circuits, and the signal transmitted through the via hole structure 150 may be radio frequency signals as well as any other type of signals.

It is appreciated that the present invention may also be applicable to multi layer PCBs, for example, a PCB having one or more routing layers positioned between the top routing layer 110 and the bottom routing layer 120. It is also appreciated that at least one of the radio frequency wire 130 may be arranged/formed on one or more inner routing layers which are in the middle of the multi layer PCB. In addition, the via hole structure 150 may be blind via hole, buried via hole or through via hole, thereby connecting a inner routing layer to the top/bottom routing layer 110/120, or connecting two inner routing layers with each other.

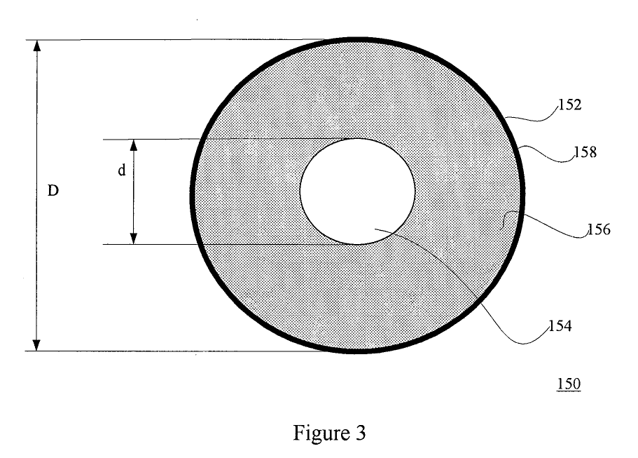

FIG. 3 is a cross-sectional view of a central portion of the via hole structure 150. The via hole structure 150 includes a connecting hole 158, an inner conductor 154, an outer conductor 152 substantially surrounding the inner conductor 154, and an insulating medium 156. The connecting hole 158 is defined on the PCB 100 with two ends of the connecting hole 158 extending to the top routing layer 110 and the bottom routing layer 120. The insulating medium 156 is positioned between the inner conductor 154 and outer conductor 152, and surrounds the inner conductor 154. As such, the function of the outer conductor 152 is similar to that of the outer mesh-shaped conductor of coaxial cables (not shown), and the function of the insulating medium 156 is similar to that of insulating material of the coaxial cables which separates an inner conductor and the outer mesh-shaped conductor.

It is appreciated that the via hole structure of the present invention is similar to the coaxial cables, so that the impedance calculation formula for the coaxial cables is also applicable to the via hole structure 150. Such formula is as follows:

$${Z}_{0} = \frac{1}{2 π} \sqrt{\frac{μ}{ɛ}} ln \frac{D}{d} \approx \frac{138 Ω}{\sqrt{{ɛ}_{r}}} {log}_{10} \frac{D}{d}$$

Wherein, D represents the inner diameter of the outer conductor 152; d represents the outer diameter of the inner conductor 154; ∈ᵣ represents the dielectric constant of the insulating medium 156 between the inner and outer conductors 154 and 152, and μ represents the space magnetic permeability. According to the above formula, the impedance of transmission wire depends only on the conductor diameters D and d, the dielectric constant ∈ of the insulating medium 165 and the space magnetic permeability μ, but is not related to other parameters, such as feeder's length, work frequency or the load impedance connected to the feeder's end. As such, through controlling the inner diameter D of the outer conductor 152, the outer diameter d of the inner conductor 154 in the via hole structure, and the dielectric constant ∈ of the insulating medium 156, impedance matching in the via hole structure may be adjusted, thereby making the impedance design of the whole circuit more precise.

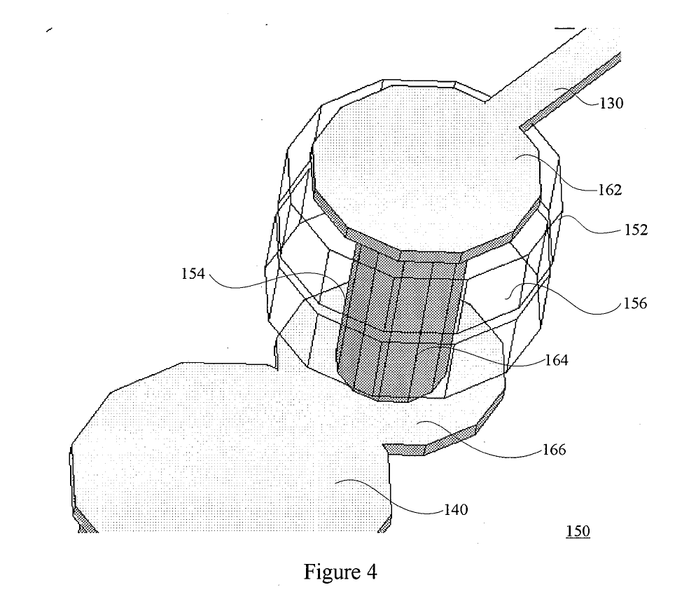

FIG. 4 is a perspective view of the via hole structure 150. The PCB 100 and the insulating medium 156 are omitted from FIG. 4 for clarity. In the illustrated embodiment, the inner wall of the connecting hole 158 is applied with a layer of metal to form the outer conductor 152 through suitable means such as plating. As such, the outer conductor 152 is in the shape of a hollow cylinder, so as to surround the inner conductor 154. Alternatively, the outer conductor 152 may also have other structures, such as mesh shaped tubes or drums. The cross section of the outer conductor 152 illustrated in FIG. 3 may be circular or polygonal. The height of the outer conductor 152 may be slightly less than the thickness of the PCB 100, thereby preventing the outer conductor 152 from being in contact of communication components such as the inner conductor 154 or the radio frequency wire 130. As such, potential electrical conduction between the outer conductor 152 and other electronic components is avoid. In addition, a gap (not shown) may be defined on the outer conductor 152 at a position adjacent to other electronic components, thereby ensuring a safe distance between the outer conductor 152 and the radio frequency wire 130 or electronic component 140. According to an exemplary embodiment, the outer conductor 152 has a thickness between 14-34 microns. The outer conductor 152 can also has other suitable thickness that benefit for the manufacture.

The inner conductor 154 is electrically connected to the circuit and/or the electronic components 140 on the top routing layer 110 and the bottom routing layer 120. Specifically, the inner conductor 154 includes a discal top portion 162, a cylindrical middle portion 164 and a discal bottom portion 166. In an embodiment, the top portion 162, the middle portion 164 and the bottom portion 166 are integrally molded. The top portion 162 is positioned on the top routing layer 110, and is electrically connected to the radio frequency wire 130 through welding or other suitable means. The length of the middle portion 164 exceeds or equals the thickness of the PCB 100 (shown in FIG. 2), and is surrounded by the outer conductor 152. The bottom portion 166 is positioned on the bottom routing layer 120 of the PCB 100, and is electrically connected to the electronic component 140 through welding or other suitable means.

The insulating medium 156 (shown in FIG. 3) fills the space between the outer conductor 152 and the inner conductor 154, particularly between the outer conductor 152 and the middle portion 164 of inner conductor 154, thereby insulating the outer conductor 152 from the inner conductor 154. The outer conductor 152 is connected to a reference voltage level, e.g., ground wire, thereby screening signals transmitted in the inner conductor 154 from electromagnetic interference in the environment.

In an exemplary embodiment, the outer conductor 152 and the inner conductor 154 are made of copper or other suitable metals. The insulating medium 156 may be made of the material listed in Table 1. Specifically in a preferred embodiment, the insulating medium 156 is made of a material having dielectric constant between 4-5.2. It is appreciated that the insulating medium 156 may also be made of other materials not listed in Table 1 in alternative embodiments.

TABLE 1

| Materials | Dielectric Constant |
|---|---|
| PTFE | 2.1 |
| Cyanate Ester/Glass | 3.2 |
| Cyanate Ester/Quartz | 2.8-3.4 |
| Polyimide-Quartz | 3.5-3.8 |
| Polyimide-Glass | 4.0-4.6 |
| Epoxy Resin-Glass (FR4) | 4.4-5.2 |
| Non-woven Aromatic Amine | 3.8-4.1 |
| (aramid) | |
| Aromatic Amine (fabric) | 3.8-4.1 |
| Pottery-filled PTFE | 6.0-10.2 |

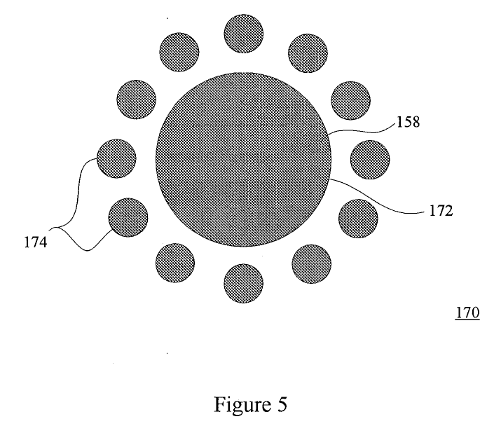

FIG. 5 is a cross-sectional view of a central portion of the via hole structure 170 according to another embodiment of the present invention. The via hole structure 170 includes an inner conductor 172 which has a structure similar to that of the inner conductor 154 illustrated in FIG. 4. The via hole structure 170 also includes a plurality of metal poles 174 arranged in a circle surrounding the inner conductor 172. Each pole 174 has a relatively smaller diameter than that of the inner conductor 172. In an exemplary embodiment, the number of the metal poles 174 may be as many as possible without affecting the structural strength of the PCB 100 (shown in FIG. 2), and the metal poles 174 are arranged as close to each other as possible. The metal poles 174 are circularly arranged around the inner conductor 172, and all metal poles 174 are connected to the ground. As such, the plurality of metal poles 174 cooperatively function as the outer conductor of a coaxial cable, and the material between the inner conductor 172 and the plurality of poles 174 in the PCB 100 functions as the insulating medium of the coaxial cables.

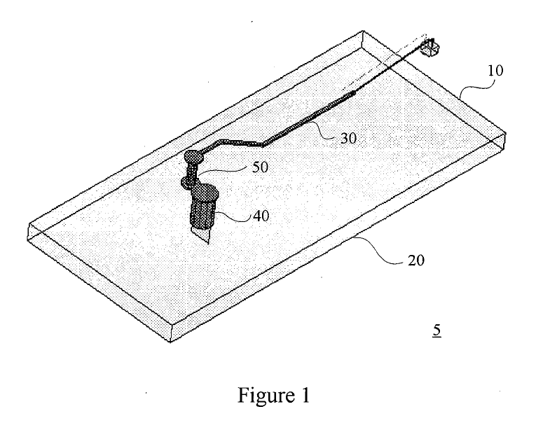

According to an embodiment of the present invention, an exemplary method may be used to manufacture the via hole structure 150 shown in FIG. 4. Firstly, the connecting hole 158 is defined between two routing layers of the PCB 100 (shown in FIG. 1), such as the top routing layer 110 and the bottom routing layer 120. A metal layer may be plated on the inner wall of the connecting hole 158 to form the outer conductor 152, and the outer conductor 152 is connected to the ground. The inner conductor 154 is then inserted into the connecting hole 158. Alternatively, the inner conductor 154 may be at least partially pre-formed and inserted into the hole 158. The insulating medium 156 is then formed the space between the outer conductor 152 and the inner conductor 154, so as to insulate the inner conductor 154 from the outer conductor 152. The inner conductor 154 is electrically connected with the circuit and/or the electronic components on the two routing layers 110 and 120, thereby realizing the connection between the two routing layers 110 and 120.

According to another embodiment of the present invention, another exemplary method may be used to manufacture the via hole structure 170 shown in FIG. 5. Firstly, a connecting hole is defined between the two routing layers of the PCB 100 (shown in FIG. 1). The connecting hole is then filled with metal to form the inner conductor 172. A plurality of conductor holes with a smaller diameter is then defined around the connecting hole, and the conductor holes are substantially arranged as a circle. In an exemplary embodiment, the conductor holes are closely arranged with respect to each other, and arranged in a circular shape around the connecting hole. In the exemplary embodiment, the size of the conductor holes may be as small as possible, and the number of conductor holes may be as many as possible without affecting the structural strength of the PCB 100. The conductor holes are filled with metal, so as to form the plurality of metal poles 174. The metal poles 174 are then connected to the ground. As such, the metal poles 174 perform a shielding function as the outer conductor, and the basic material of the PCB 100 form the insulating medium between the inner conductor 172 and the outer conductor 174.

According to the exemplary embodiments of the present invention, in the via hole structure of the PCB, the outer conductor surrounds the inner conductor, and the outer conductor is insulated from the inner conductor by the insulating medium therebetween. When the signal is transmitted through the via hole structure from outside environment, The outer conductor insulates the signal, thereby minimizing radiation loss as well as influence of external disturbance.

While the inventions have been described with reference to the certain illustrated embodiments, the words that have been used herein are words of description, rather than words of limitation. Changes may be made, within the purview of the appended claims, without departing from the scope and spirit of the invention in its aspects. For example, radio frequency wire 130 and electronic component 140 can be either any electronic component, or only a weld toe, and the signal through the PCB can be radio frequency signals as well as any other type of signals. Although the inventions have been described herein with reference to particular structures, acts, and materials, the invention is not to be limited to the particulars disclosed, but rather can be embodied in a wide variety of forms, some of which may be quite different from those of the disclosed embodiments, and extends to all equivalent structures, acts, and, materials, such as are within the scope of the appended claims.

What is claimed is:

1. A printed circuit board (PCB) comprising:
a substrate having a first side and a second side;
a first routing layer on the first side of the substrate;
a second routing layer on the second side of the substrate; and
a via hole structure comprising a connecting hole formed in the substrate extending between the first routing layer and the second routing layer, an inner conductor at least partially positioned in the connecting hole, and an outer conductor substantially surrounding the inner conductor.

2. The PCB according to claim 1, wherein the inner conductor is made of a conductive material including copper.

3. The PCB according to claim 1, further comprising an insulating medium between the inner conductor and the outer conductor, wherein the insulating medium includes a dielectric material having a relative dielectric constant between 4 to 5.2.

4. The PCB according to claim 1, wherein the outer conductor comprises a metal layer disposed on an inner wall of the connecting hole.

5. The PCB according to claim 1, wherein the outer conductor comprises a plurality of metal conductors arranged around the connecting hole, the metal conductors being positioned in a plurality of conductor holes formed in the substrate and having a diameter less than a diameter of the connecting hole, the plurality of metal conductors being configured to be connected to a reference voltage level.

6. The PCB according to claim 1, wherein the first routing layer comprises a radio frequency circuit, and the inner conductor in the via hole structure is connected to the radio frequency circuit.

7. The PCB according to claim 1, further comprising at least one inner routing layer positioned between the first routing layer and second routing layer, wherein the inner conductor is electrically insulated from the inner routing layer.

8. A method for forming a via hole structure in a printed circuit board (“PCB”) including a first routing layer and a second routing layer, comprising the steps of:
defining a connecting hole on the PCB and between the first and second routing layers;
plating metal on an inner wall of the connecting hole to form an outer conductor;
forming an inner conductor in the connecting hole, electrically connected to the first and the second routing layers; and
disposing an insulating medium between the outer conductor and inner conductor.

9. The method according to claim 8, wherein the step of plating metal comprises plating copper on the inner wall of the connecting hole.

10. The method according to claim 8, wherein the step of disposing the insulating medium comprises disposing a dielectric material having a dielectric constant between 4 to 5.2.

11. The method according to claim 8, further comprising the step of providing a radio frequency circuit on at least one of the first and second routing layers.

12. The method according to claim 11, further comprising the step of electrically coupling the inner conductor to the radio frequency circuit.

13. The method according to claim 8, further comprising the steps of:
providing at least one inner routing layer between the first routing layer and second routing layer; and
electrically insulating the inner conductor from the inner routing layer.

14. A method for forming a via hole structure in a printed circuit board (“PCB”) including a first routing layer and a second routing layer, comprising the steps of:
defining a connecting hole in the PCB and between the first and the second routing layers;
filling the connecting hole with metal to form an inner conductor electrically coupled to the first and second routing layers;
defining a plurality of conductor holes around the connecting hole, each conductor hole having a diameter smaller than a diameter of the connecting hole; and
filling the plurality of conductor holes with metal; and
electrically connecting metal in the plurality of conductor holes to a reference voltage level.

15. The method according to claim 14, wherein the step of defining a plurality of conductor holes around the connecting hole includes arranging the plurality of conductor holes in a circle around the connecting hole.

16. The method according to claim 14, wherein the step of filling the connecting hole with metal comprises filling the connecting hole with copper.

17. The method according to claim 14, further comprising the step of providing a radio frequency circuit on at least one of the first and second routing layers.

18. The method according to claim 17, further comprising the step of electrically coupling the inner conductor to the radio frequency circuit.

19. The method according to claim 14, further comprising the step of providing at least one inner routing layer between the first routing layer and the second routing layer, the inner conductor passing through the inner routing layer and being electrically disconnected from the inner routing layer.
